(19) United States
(12) Patent Application Publication
(10) Pub. No.: US 2026/0164944 A1
(43) Pub. Date: Jun. 11, 2026

(54) DISPLAY DEVICE AND ELECTRONIC DEVICE INCLUDING THE SAME

(71) Applicant: Samsung Display Co., Ltd., Yongin-Si (KR)

(72) Inventors: SOOYOUN KIM, Yongin-si (KR); Hee Jun Yang, Yongin-si (KR); EUNJIN KWAK, Yongin-si (KR); EONJOO LEE, Yongin-si (KR)

(21) Appl. No.: 19/391,025

(22) Filed: Nov. 17, 2025

(30) Foreign Application Priority Data
Dec. 10, 2024 (KR) 10-2024-0183043

(51) Int. Cl. H10K 59/122; H10K 59/38; H10K 59/80

(52) U.S. Cl. CPC H10K 59/122; H10K 59/38; H10K 59/80521; H10K 59/8731

(57) ABSTRACT

Provided are a display device and an electronic device including the same. The display device includes a substrate including a display area and a peripheral area outside the display area, a plurality of barriers arranged on the substrate, a plurality of pixels wherein a pixel in the plurality of pixels is arranged on a barrier in the plurality of barriers and wherein the pixel in the plurality of pixels includes a pixel electrode, an intermediate layer, and a counter electrode, and a spacer arranged between at least two pixels in the plurality of pixels.

### CROSS-REFERENCE TO RELATED APPLICATION

This application is based on and claims priority under 35 U.S.C. § 119 to Korean Patent Application No. 10-2024-0183043, filed on Dec. 10, 2024, in the Korean Intellectual Property Office, the disclosure of which is incorporated by reference herein in its entirety.

### BACKGROUND

### 1. Field

The present disclosure relates to a display device and an electronic device including the same.

### 2. Description of Related Art

As the demand for display devices grows, the need for display devices that may be used for various purposes is also increasing. In line with this trend, display devices are becoming increasingly larger and thinner, and the need for display devices that are larger and thinner while having accurate and vivid colors is also increasing.

### SUMMARY

Embodiments of the present disclosure aim to provide a display device capable of improving optical characteristics and an electronic device including the display device.

However, these problems are simply for example, and the problems to be solved by the present disclosure are not limited thereto.

According to an aspect of the present disclosure, a display device includes a substrate including a display area and a peripheral area outside the display area, a plurality of barriers arranged on the substrate, a plurality of pixels wherein a pixel in the plurality of pixels is arranged on a barrier in the plurality of barriers and wherein the pixel in the plurality of pixels comprises a pixel electrode, an intermediate layer, and a counter electrode, and a spacer arranged between at least two pixels in the plurality of pixels.

The pixel electrode may be arranged on the barrier and include a pixel-defining film arranged on the barrier to cover at least a part of the pixel electrode.

The barrier may include a base layer arranged on the substrate, a body layer arranged on the base layer, and a top layer arranged on the body layer.

The base layer may be integral with the substrate and overlaps the plurality of barriers.

The body layer may have a width that becomes narrower in a direction away from the substrate.

The barrier may include a first tip has the top layer that protrudes outward more than the body layer to overhang the body layer.

The intermediate layer may be arranged to surround at least a part of the pixel electrode and the barrier.

The intermediate layer may be further arranged on the base layer.

The intermediate layer may be arranged such that a part is arranged on the pixel electrode and a part is arranged on the base layer and wherein the part arranged on the pixel electrode is spaced apart from each other the part arranged on the base layer.

The counter electrode may be arranged to surround at least a part of the intermediate layer and the barrier.

The counter electrode may include a concave portion toward the body layer between the top layer and the base layer.

The spacer may have a height greater than that of the pixel.

The spacer may be arranged on a spacer barrier in the plurality of barriers wherein the pixel is not arranged on the spacer barrier.

The spacer barrier may include a base layer arranged on the substrate, a body layer arranged on the base layer, and a top layer arranged on the body layer.

The spacer barrier may include a second tip that has the top layer protrudes outward more than the body layer to overhang the body layer.

The display device may further include a first inorganic layer arranged on the pixel and the spacer.

The display device may further include a color filter arranged on the first inorganic layer and arranged to overlap the pixel.

The display device may further include a first organic layer arranged on the first inorganic layer.

The display device may further include a second inorganic layer arranged on the first organic layer.

According to another aspect of the present disclosure, an electronic device includes a controller configured to generate a scan input signal, a power module configured to generate a scan input voltage, and a display device divided into a display area in which a pixel circuit is arranged and a peripheral area located outside the display area and including a pad area, in which the display device includes a substrate, a plurality of barriers arranged on the substrate, a plurality of pixels wherein a pixel in the plurality of pixels is arranged on a barrier in the plurality of barriers and wherein the pixel in the plurality of pixels includes a pixel electrode, an intermediate layer, and a counter electrode, and a spacer arranged between the pixels.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a perspective view schematically showing a display device according to an embodiment of the present disclosure.

FIG. 2 is a cross-sectional view schematically showing an example of a cross-section I-I′ of FIG. 1.

FIG. 3 is a plan view schematically showing a part of the display device of FIG. 1.

FIG. 4 is a circuit diagram showing an example of one pixel of the display device of FIG. 1.

FIG. 5 is a cross-sectional view schematically showing an example of a cross-section of a pixel of FIG. 3.

FIG. 6 is a cross-sectional view schematically showing an example of a cross-section II-II′ of FIG. 3.

FIG. 7 is an enlarged view of a portion X of FIG. 6.

FIG. 8 is an enlarged view of a portion Y of FIG. 6.

FIG. 9 is a view schematically showing another example of a cross-section II-II′ of FIG. 7.

FIG. 10 is a view schematically showing another example of the cross-section II-II′ of FIG. 7.

FIG. 11 is a block diagram schematically showing an example of an electronic device according to embodiments of the present disclosure.

### DETAILED DESCRIPTION

The present disclosure may have various modifications thereto and various embodiments, and thus particular embodiments will be illustrated in the drawings and described in detail in a detailed description. Effects and features of the present disclosure, and methods for achieving them will become clear with reference to the embodiments described later in detail together with the drawings. However, the present disclosure is not limited to the embodiments disclosed below and may be implemented in various forms.

In the following embodiments, the terms such as first, second, etc., have been used to distinguish one component from other components, rather than limiting.

In the following embodiments, singular forms include plural forms unless apparently indicated otherwise contextually.

In the following embodiments, the terms “include”, “have”, or the like, are intended to mean that there are features, or components, described herein, but do not preclude the possibility of adding one or more other features or components.

In the following embodiments, when a portion, such as a film, a region, a component, etc., is present on or above another portion, this case may include not only a case where it is directly on the other portion, but also a case where another film, region, component, etc., is arranged between the portion and the other portion.

In the examples below, terms such as connect or combine do not necessarily imply a direct and/or fixed connection or combination of two members, unless the context clearly indicates otherwise, and do not exclude the presence of another member between the two members.

In the drawings, the size of components may be exaggerated or reduced for convenience of description. In some embodiments, since the size and thickness of each component shown in the drawings are arbitrarily shown for convenience of description, the present disclosure is not necessarily limited to the illustrated bar.

Hereinafter, preferred embodiments of the present disclosure will be described in detail with reference to the attached drawings. When describing with reference to the drawings, identical or corresponding components are given the same drawing reference numerals and redundant descriptions thereof will be omitted.

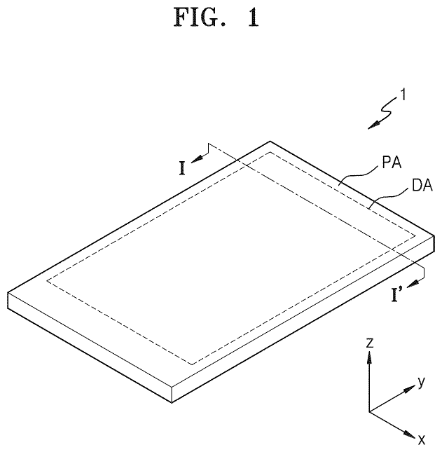

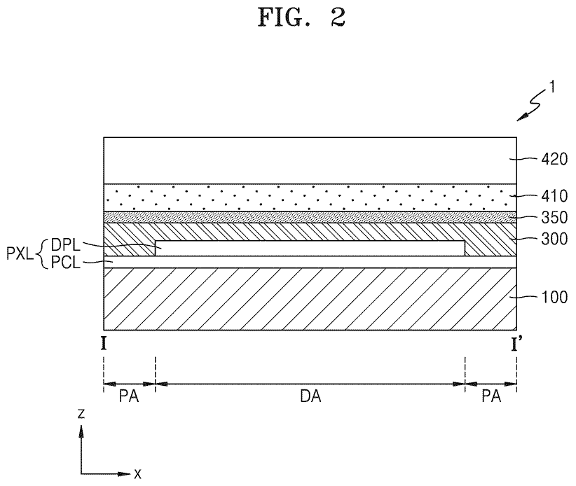

FIG. 1 is a perspective view schematically showing a display device according to an embodiment of the present disclosure, and FIG. 2 is a cross-sectional view schematically showing an example of a cross-section I-I′ of FIG. 1.

Referring to FIG. 1, a display device 1 according to an embodiment of the present disclosure may include a display area DA and a peripheral area PA. The peripheral area PA may be arranged to surround the display area DA on the periphery of the display area DA. The peripheral area PA may have various wires and driving circuit units that may transmit electrical signals to the display area DA. The display device 1 may provide a selected image by using light emitted from a plurality of pixels arranged in the display area DA. Although not shown, the display device 1 may be capable of bending including a bending region partially located in a region of the peripheral area PA.

The display device 1 may be a display device such as an organic light-emitting display, an inorganic light-emitting display (or an inorganic electro-luminescence EL display), or a quantum dot light-emitting display. Hereinafter, a description will be made using an organic light-emitting display device as an example. The display device 1 may be implemented with various types of electronic devices such as mobile phones, laptop computers, smart watches, etc.

As shown in FIG. 2, the display device 1 may include a substrate 100, a pixel layer PXL on the substrate 100, an encapsulating member 300 sealing the pixel layer PXL, an light control layer 350 on the encapsulating member 300, a bonding layer 410 on the light control layer 350, and a functional layer 420 on the bonding layer 410, which are sequentially laminated in a thickness direction (z direction).

The substrate 100 may include a glass material or a polymer resin. For example, the substrate 100 may include a glass material containing SiO2 as a main component, or may include various materials having flexible or bendable properties, for example, a resin or a reinforced plastic. Although not shown, the substrate 100 may be capable of bending including a bending region partially located in a region of the peripheral area PA.

On the substrate 100, the pixel layer PXL may be formed. The pixel layer PXL may include a display element layer DPL including display elements arranged for each pixel and a pixel circuit layer PCL including a pixel circuit and insulating layers arranged for each pixel. The display element layer DPL may be arranged on the pixel circuit layer PCL, and a plurality of insulating layers may be arranged between the pixel circuit and the display element. In some implementations, wires and insulating layers of the pixel circuit layer PCL may extend to the peripheral area PA.

The encapsulating member 300 may be a thin-film encapsulating layer. The thin-film encapsulating layer may include at least one inorganic encapsulating layer and at least one organic encapsulating layer. The flexibility of the display device 1 may be improved by including the substrate 100 having a polymer resin and the encapsulating member 300 being the thin-film encapsulating layer having the inorganic encapsulating layer and the organic encapsulating layer.

The light control layer 350 may control a path of light emitted from the display element of the display element layer DPL and improve the light emission efficiency of the display device 1. As described below, the light control layer 350 may change the path of the light emitted from the display element together with the bonding layer 410 to increase the light extraction efficiency of the display device 1.

The bonding layer 410 may bond the functional layer 420 on the encapsulating member 300 to a layer under the functional layer 420, for example, the light control layer 350. The bonding layer 410 may improve the light extraction efficiency of the display device 1 by having a higher refractive index than the light control layer 350.

The functional layer 420 may include a polarizing layer. The polarizing layer may transmit only the light that vibrates in the same direction (e.g. the light has a particular wave orientation) as a polarization axis and absorb or reflect the light that vibrates in the other directions (e.g. the light having other wave orientations), out of the light emitted from the display element of the display element layer DPL. The functional layer 420 may further include an optical film, a window, etc. for reflecting external light.

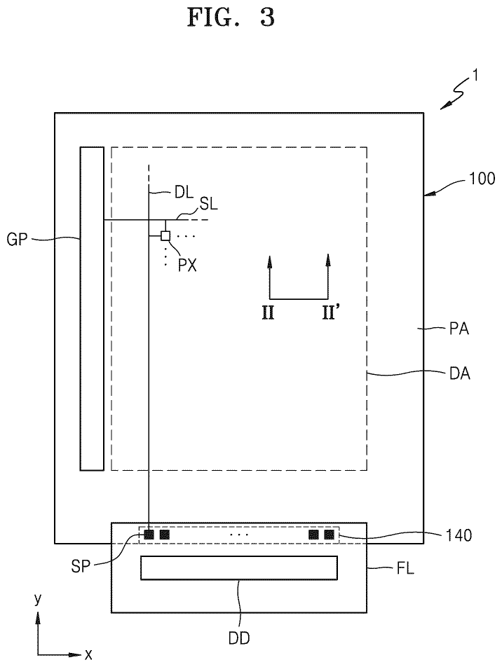

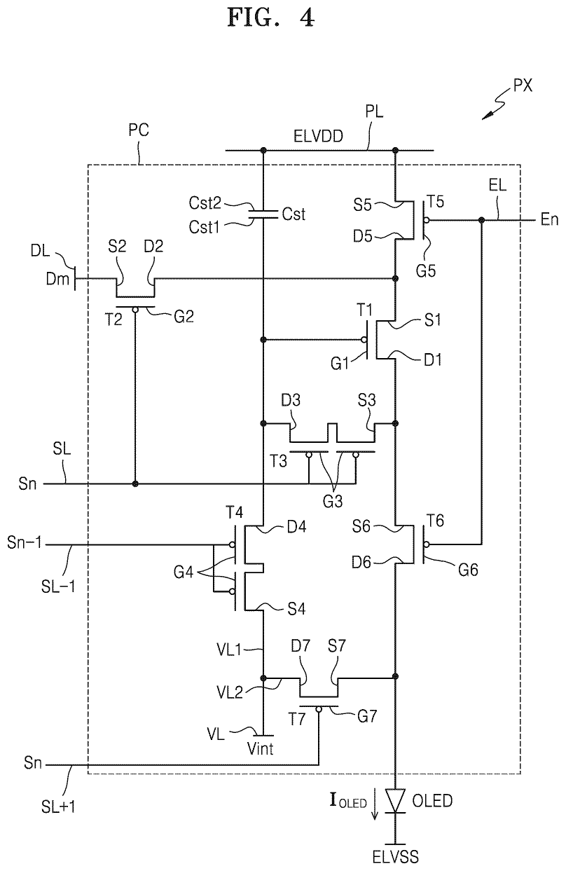

FIG. 3 is a plan view schematically showing a part of the display device of FIG. 1, and FIG. 4 is a circuit diagram showing an example of one pixel of the display device of FIG. 1.

Referring to FIG. 3, the substrate 100 may include the display area DA and the peripheral area PA. The peripheral area PA may be arranged to surround the display area DA on the periphery of the display area DA.

In the display area DA on an upper portion of the substrate 100, a plurality of pixels PX may be arranged in a selected pattern in a first direction (an x direction, a row direction) and a second direction (a y direction, a column direction).

In the peripheral area PA on the upper portion of the substrate 100, a scan driver GP that provides a scan signal to each pixel PX, a data driver DD that provides a data signal to each pixel PX, and main power wires (not shown) for providing a first power voltage ELVDD (see FIG. 4) and a second power voltage ELVSS (see FIG. 4) may be arranged. A pad portion 140 in which a plurality of signal pads SP connected to a data line DL are arranged may be located in the peripheral area PA on the upper portion of the substrate 100.

The scan driver GP may include an oxide semiconductor TFT gate driver circuit (OSG) or an amorphous silicon TFT gate driver circuit (ASG). In FIG. 3, the scan driver GP is shown as being positioned adjacent to a side of the substrate 100, but depending on an embodiment, the scan driver GP may be positioned adjacent to each of two facing sides of the substrate 100.

FIG. 3 shows a chip on film (COF) implementation in which the data driver DD is placed on a film FL electrically connected to the signal pads SP arranged on the substrate 100. According to embodiments, the data driver DD may be arranged directly on the substrate 100 in a chip on glass (COG) or chip on plastic (COP) implementation. The data driver DD may be electrically connected to a flexible printed circuit board (FPCB).

Referring to FIG. 4, one pixel PX may include a pixel circuit PC and an organic light-emitting diode (OLED) electrically connected to the pixel circuit PC.

The pixel circuit PC may include a plurality of transistors T1 to T7 and a storage capacitor Cst, as shown in FIG. 4. The transistors T1 to T7 and the storage capacitors Cst may be connected to signal lines SL, SL−1, SL+1, EL, and DL, a first initialization voltage line VL1, a second initialization voltage line VL2, and a driving voltage line PL.

The signal lines SL, SL−1, SL+1, EL, and DL may include a scan line SL transmitting a scan signal Sn, a previous scan line (SL−1) transmitting a previous scan signal (Sn−1) to a first initialization transistor T4, a subsequent scan line (SL+1) transmitting a scan signal Sn to a second initialization transistor T7, a light emission control line EL transmitting a light emission control signal En to an operation control transistor T5 and a light emission control transistor T6, and a data line DL intersecting the scan line SL and transmitting a data signal Dm. The driving voltage line PL may transmit a driving voltage ELVDD to a driving transistor T1, the first initialization voltage line VL1 may transmit an initialization voltage Vint to the first initialization transistor T4, and the second initialization voltage line VL2 may transmit the initialization voltage Vint to the second initialization transistor T7.

A driving gate electrode G1 of the driving transistor T1 may be connected to a first electrode Cst1 of a storage capacitor Cst, a driving source electrode S1 of the driving transistor T1 may be connected to the driving voltage line PL via the operation control transistor T5, and a driving drain electrode D1 of the driving transistor T1 may be electrically connected to a pixel electrode of a main OLED via the light emission control transistor T6. The driving transistor T1 may receive the data signal Dm according to a switching operation of a switching transistor T2 and supply a driving current IOLED to the OLED.

A switching gate electrode G2 of the switching transistor T2 may be connected to the scan line SL, a switching source electrode S2 of the switching transistor T2 may be connected to the data line DL, and a switching drain electrode D2 of the switching transistor T2 may be connected to the driving source electrode S1 of the driving transistor T1 and to the driving voltage line PL via the operation control transistor T5. The switching transistor T2 may be turned on according to the scan signal Sn received through the scan line SL and perform a switching operation to transmit the data signal Dm, transmitted through the data line DL, to the driving source electrode S1 of the driving transistor T1.

A compensation gate electrode G3 of a compensation transistor T3 may be connected to the scan line SL, a compensation source electrode S3 of the compensation transistor T3 may be connected to the driving drain electrode D1 of the driving transistor T1 and a pixel electrode of the OLED via the light emission control transistor T6, and a compensation drain electrode D3 of the compensation transistor T3 may be connected to the lower (first) electrode Cst1 of the storage capacitor Cst, a first initialization drain electrode D4 of the first initialization transistor T4, and the driving gate electrode G1 of the driving transistor T1. The compensation transistor T3 may be turned on according to the scan signal Sn received through the scan line SL to electrically connect the driving gate electrode G1 and the driving drain electrode D1 of the driving transistor T1 for diode-connection of the driving transistor T1.

A first initialization gate electrode G4 of the first initialization transistor T4 may be connected to the previous scan line (SL−1), a first initialization source electrode S4 of the first initialization transistor T4 may be connected to the first initialization voltage line VL1, and the first initialization drain electrode D4 of the first initialization transistor T4 may be connected to the lower (first) electrode Cst1 of the storage capacitor Cst, the compensation drain electrode D3 of the compensation transistor T3, and the driving gate electrode G1 of the driving transistor T1. The first initialization transistor T4 may be turned on according to the previous scan signal (Sn−1) received through the previous scan line (SL−1) and perform an initialization operation of transmitting the initialization voltage Vint to the driving gate electrode G1 of the driving transistor T1 to initialize the voltage of the driving gate electrode G1 of the driving transistor T1.

An operation control gate electrode G5 of the operation control transistor T5 may be connected to the light emission control line EL, an operation control source electrode S5 of the operation control transistor T5 may be connected to the driving voltage line PL, and an operation control drain electrode D5 of the operation control transistor T5 may be connected to the driving source electrode S1 of the driving transistor T1 and the switching drain electrode D2 of the switching transistor T2.

A light emission control gate electrode G6 of the light emission control transistor T6 may be connected to the light emission control line EL, a light emission control source electrode S6 of the light emission control transistor T6 may be connected to the driving drain electrode D1 of the driving transistor T1 and the compensation source electrode S3 of the compensation transistor T3, and a light emission control drain electrode D6 of the light emission control transistor T6 may be electrically connected to a second initialization source electrode S7 of the second initialization transistor T7 and the pixel electrode of the OLED.

The motion control transistor T5 and the light emission control transistor T6 may be simultaneously turned on according to the light emission control signal En received through the light emission control line EL, such that the driving voltage ELVDD may be transmitted to the main OLED to cause the driving current IOLED to flow to the OLED.

A second initialization gate electrode G7 of the second initialization transistor T7 may be connected to the scan line (SL+1), the second initialization source electrode S7 of the second initialization transistor T7 may be connected to the light emission control drain electrode D6 of the light emission control transistor T6 and the pixel electrode of the main OLED, and a second initialization drain electrode D7 of the second initialization transistor T7 may be connected to the second initialization voltage line VL2.

As the scan line SL and the subsequent scan line (SL+1) are electrically connected to each other, the same scan signal Sn may be applied to the scan line SL and the subsequent scan line (SL+1). Thus, the second initialization transistor T7 may be turned on according to the scan signal Sn received through the scan line (SL+1) to initialize the pixel electrode of the OLED.

An upper (second) electrode Cst2 of the storage capacitor Cst may be connected to the driving voltage line PL, and a common electrode of the OLED may be connected to a common voltage ELVSS. Thus, the OLED may display an image by receiving the driving current IOLED from the driving transistor T1 and emitting light.

In FIG. 4, the compensation transistor T3 and the first initialization transistor T4 are illustrated as having dual gate electrodes, but in some implementations, the compensation transistor T3 and the first initialization transistor T4 may each have a single gate electrode instead.

Although FIG. 4 describes a structure for one pixel circuit PC of the plurality of pixels PX, each pixel in the plurality of pixels may have the same or similar pixel circuit PC. The plurality of pixels PX may be arranged to form a plurality of rows, and, the first initialization voltage line VL1, the previous scan line (SL−1), the second initialization voltage line VL2, and the subsequent scan line (SL+1) may be shared among neighboring pixels.

For example, the first initialization voltage line VL1 and the previous scan line (SL−1) may be electrically connected to a second initialization transistor of another pixel circuit PC arranged in the second direction (a y direction). Thus, the previous scan signal applied to the previous scan line (SL−1) may be transmitted as a subsequent scan signal to the second initialization transistor of the other pixel circuit PC. Similarly, the second initialization voltage line VL2 and the subsequent scan line (SL+1) may be electrically connected to the first initialization transistor of another pixel circuit PC arranged adjacently in the second direction y in the drawing to transmit the previous scan signal and the initialization voltage.

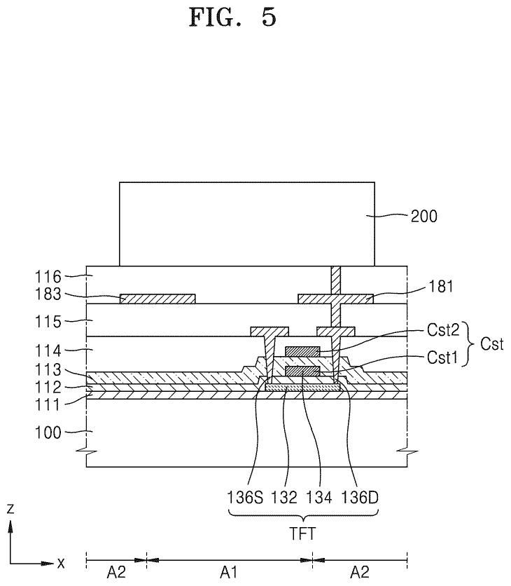

FIG. 5 is a cross-sectional view schematically showing an example of a cross-section of a pixel of FIG. 3.

Referring to FIG. 5, a buffer layer 111 may be formed on the substrate 100 to prevent impurities from penetrating into a semiconductor layer of a thin-film transistor.

The substrate 100 may be formed of various materials such as glass, metal, plastic, etc. In an embodiment, the substrate 100 may be a flexible substrate, which may include a polymer resin, such as polyether sulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate PC, or cellulose acetate propionate (CAP).

The buffer layer 111 may include an inorganic insulating material such as silicon nitride or silicon oxide, and may be a single layer or multi-layers.

A thin-film transistor TFT, a capacitor, and an OLED 200 electrically connected to the thin-film transistor TFT may be arranged on the substrate 100. For example, the capacitor may be the storage capacitor Cst described in FIG. 4. The OLED 200 being electrically connected to the thin-film transistor TFT may be understood as meaning that the pixel electrode is electrically connected to the thin-film transistor TFT. The thin-film transistor TFT may be the driving transistor T1 of FIG. 4.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polycrystalline silicon, or an organic semiconductor material. The gate electrode 134 may be formed as a single layer or multi-layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), taking into account adhesion to adjacent layers, surface flatness of the laminated layers, processability, etc.

A gate insulating layer 112 including an inorganic material such as silicon oxide, silicon nitride, and/or silicon oxynitride may be interposed between the semiconductor layer 132 and the gate electrode 134. A first interlayer insulating layer 113 and a second interlayer insulating layer 114 including an inorganic material such as silicon oxide, silicon nitride and/or silicon oxynitride may be arranged among the gate electrode 134, a source electrode 136S, and a drain electrode 136D. The source electrode 136S and the drain electrode 136D may each be electrically connected to the semiconductor layer 132 through contact holes formed in the gate insulating layer 112, the first interlayer insulating layer 113, and the second interlayer insulating layer 114.

The source electrode 136S and the drain electrode 136D may be formed as a single layer or multi-layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

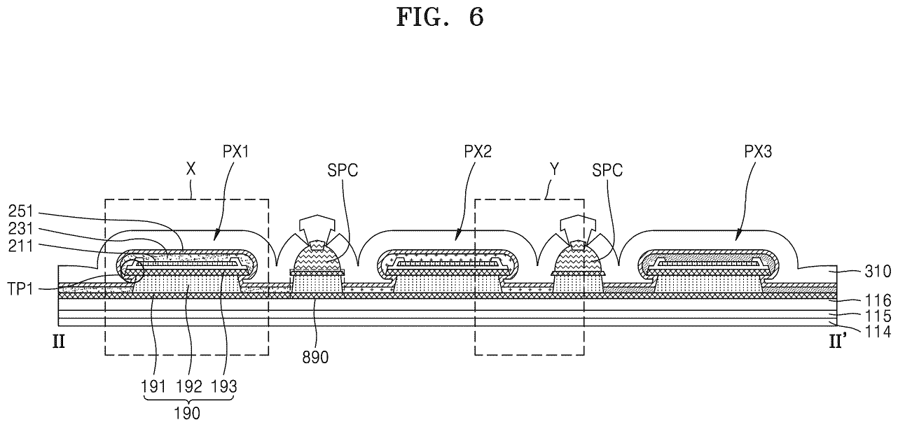

The storage capacitor Cst may include the lower electrode Cst1 and the second electrode Cst2 that overlap each other with the first interlayer insulating layer 113 therebetween. The storage capacitor Cst may overlap the thin-film transistor TFT. In FIG. 6, the gate electrode 134 of the thin-film transistor TFT is illustrated as the lower electrode Cst1 of the storage capacitor Cst. In another embodiment, the storage capacitor Cst may not overlap the thin film transistor TFT. The storage capacitor Cst may be covered with the second interlayer insulating layer 114.

A pixel circuit including the thin-film transistor TFT and the storage capacitor Cst may be covered with a first insulating layer 115 and a second insulating layer 116. The first insulating layer 115 and the second insulating layer 116 may be organic insulating layers that are planarizing insulating layers. The first insulating layer 115 and the second insulating layer 116 may include organic insulating materials such as general-purpose polymers such as polymethylmethacrylate (PMMA) or polystyrene (PS), polymer derivatives having phenolic groups, acrylic polymers, imide polymers, aryl ether polymers, amide polymers, fluorinated polymers, p-xylene polymers, vinyl alcohol polymers, and blends thereof. In an embodiment, the first insulating layer 115 and the second insulating layer 116 may include polyimide.

A display element, for example, the OLED 200, may be arranged on the second insulating layer 116. The organic light-emitting diode 200 may include a pixel electrode, an intermediate layer, and a counter electrode.

The pixel electrode may be arranged on the second insulating layer 116 and may be connected to the thin-film transistor TFT through a connecting electrode 181 on the first insulating layer 115. A wire 183, such as the data line DL, the driving voltage line PL, etc., may be arranged on the first insulating layer 115.

The pixel electrode may include a conductive oxide such as indium tin oxide (ITO), indium zinc oxide (IZO), zinc oxide (ZnO), indium oxide (In2O3), indium gallium oxide (IGO), or aluminum zinc oxide (AZO). In another embodiment, the pixel electrode may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode may further include a film formed of ITO, IZO, ZnO or In2O3 located above and/or below the aforementioned reflective film.

The intermediate layer may include a light-emitting layer. The light-emitting layer may include a polymer or low-molecular organic material that emits light of a selected color. In an embodiment, the intermediate layer may include a first functional layer below the light-emitting layer and/or a second functional layer above the light-emitting layer. The first functional layer and/or the second functional layer may include a layer that is integral across a plurality of pixel electrodes, or may include a layer patterned to correspond to each of the plurality of pixel electrodes.

The first functional layer may be a single-layer or multi-layer structure. For example, when the first functional layer is formed of a polymer material, the first functional layer is a single-layer hole transport layer (HTL) and may be formed of polyethylene dihydroxythiophene (poly-(3,4)-ethylene-dihydroxy thiophene (PEDOT)) or polyaniline (PANI). When the first functional layer is formed of a low-molecular material, the first functional layer may include a hole injection layer (HIL) and a HTL.

The second functional layer is optional and may be excluded from some implementations. For example and without limitation, when the first functional layer and the light-emitting layer are formed of a polymer material, having a second functional layer may improve the characteristics of an OLED. The second functional layer may be a single-layer or multi-layer. The second functional layer may include an electron transport layer (ETL) and/or an electron injection layer (EIL).

A counter electrode may be formed integrally in the plurality of OLEDs 200 in the display area DA and may face a plurality of pixel electrodes.

The counter electrode may be arranged on the intermediate layer. The counter electrode may include a conductive material with a low work function. For example, the counter electrode may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In some implementations, the counter electrode may further include a layer such as ITO, IZO, ZnO or In₂O₃ on the (semi) transparent layer including the aforementioned material.

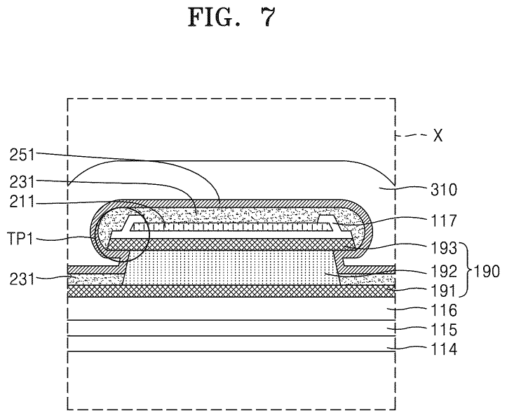

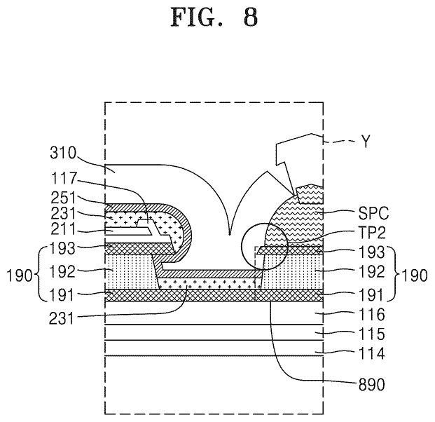

FIG. 6 is a cross-sectional view schematically showing an example of a cross-section II-II′ of FIG. 3, FIG. 7 is an enlarged view of a portion X of FIG. 6, and FIG. 8 is an enlarged view of a portion Y of FIG. 6.

Referring to FIGS. 6 to 8, the display device 1 according to an embodiment of the present disclosure may include the substrate 100 having a display area and a peripheral area outside the display area, a barrier 190 on the substrate 100, a pixel including a pixel electrode 211, an intermediate layer 231, and a counter electrode 251, and a spacer SPC.

The substrate 100 may include a display area and a peripheral area outside the display area.

A plurality of barriers 190 may be arranged on the substrate 100. For example, the plurality of barriers 190 may be arranged spaced apart from each other on the substrate 100.

In an embodiment, the barrier 190 may be arranged on the second insulating layer 116. However, the present disclosure is not limited thereto, and a layer may be further arranged between the barrier 190 and the second insulating layer 116.

The barrier 190 may be arranged on the substrate 100 and formed to extend in a direction away from the substrate 100.

In an embodiment, the barrier 190 may be conductive. In this case, the barrier 190 may be electrically connected to each other by directly contacting the counter electrode 251. When the barrier 190 and the counter electrode 251 are electrically connected to each other, the counter electrode 251 may be supplied with voltage.

In an embodiment, the barrier 190 may have a layer structure.

As a specific example, the barrier 190 may include a base layer 191, a body layer 192, and a top layer 193. For example, the body layer 192 may be arranged on the base layer 191, and the top layer 193 may be arranged on the body layer 192.

The base layer 191 may be arranged on the substrate 100. For example, the base layer 191 may be arranged on the second insulating layer 116. However, the present disclosure is not limited thereto, and a layer may be further arranged between the base layer 191 and the second insulating layer 116.

In an embodiment, the base layer 191 may be integrally formed on the substrate 100 to overlap the plurality of barriers 190. For example, the base layer 191 may be integrally formed on the substrate 100 (see for example FIG. 5) to form a lowermost layer among the plurality of barriers 190, as shown in FIG. 6, etc. That is, when expressed from another perspective, it may mean that after the base layer 191 is formed on the substrate 100, the plurality of body layers 192 and the top layer 193 may be arranged on the base layer 191.

The body layer 192 may be arranged on the base layer 191.

In an embodiment, the barrier 190 may have an undercut shape. In a specific embodiment, the body layer 192 may be formed in a shape having a width becoming narrower in a direction away from the substrate 100. For example, the body layer 192 may be roughly formed to have a trapezoidal cross section with a longer length of a side closer to the substrate 100.

The top layer 193 may be arranged on the body layer 192.

In an embodiment, the barrier 190 may include a first tip TP1. For example, the top layer 193 may be formed to protrude outward more than the body layer 192. The term “outward” may mean that the top layer 193 is formed wider left and right than the body layer 192 with respect to FIG. 7.

The first tip TP1 may include a portion of the top layer 193, which protrudes outward more than the body layer to overhang the body layer 192. As described below, the first tip TP1 may include at least a part of a third insulating layer 117 formed on the top layer 193.

Each pixel in the plurality of pixels may be arranged on a barrier in the plurality of barriers 190.

The pixels may not be arranged on every barrier in the plurality of barriers 190, but may be formed on some of the plurality of barriers 190. For example and without limitation, the pixels may be arranged on every second barrier, third barrier, further barrier etc. of the plurality of barriers 190.

The pixels may include a first pixel PX1, a second pixel PX2, and a third pixel PX3. The first pixel PX1, the second pixel PX2, and the third pixel PX3 may each emit light of different colors. For example, the first pixel PX1 may emit red light, the second pixel PX2 may emit green light, and the third pixel PX3 may emit blue light.

Each pixel may include the pixel electrode 211, the intermediate layer 231, and the counter electrode 251.

The pixel electrode 211 may be arranged on the barrier 190. For example, the pixel electrode 211 may be arranged on the top layer 193.

In an embodiment, the third insulating layer 117 may be arranged on the top layer 193 of the barrier 190. The third insulating layer 117 may be a pixel-defining film.

The pixel-defining film 117 may be arranged to cover at least a part of the pixel electrode 211. That is, referring to FIG. 7, the pixel-defining film 117 may cover a part of the edge of the pixel electrode 211 arranged on the substrate 100. Thus, the pixel-defining film 117 may include an opening that allows a part of the pixel electrode 211 to be exposed. When expressed from another aspect, it may mean that a light-emitting region is defined by the opening.

In an embodiment, the third insulating layer 117 may be arranged between the pixel electrode 211 and the top layer 193. In this case, the third insulating layer 117 may extend from between the pixel electrode 211 and the top layer 193 toward the outside of the pixel electrode 211 and cover at least a part of the edge of the pixel electrode 211.

The intermediate layer 231 may be arranged on the pixel electrode 211.

The intermediate layer 231 may include a light-emitting layer including a polymer or a low-molecular organic material that emits light of a selected color.

In an embodiment, the intermediate layer 231 may be arranged to surround the pixel electrode 211 and a part of the barrier 190. Specifically, the intermediate layer 231 may be arranged to surround the pixel electrode 211, a part of the pixel-defining film 117, and a part of the top layer 193, as shown in FIG. 7.

In an embodiment, the intermediate layer 231 may be further arranged on the base layer 191. That is, the intermediate layer 231 may be arranged on the base layer 191, but may be arranged to form a layer between the barriers 190.

In more detail, the display device 1 according to the present disclosure may include the barrier 190 of the above-described structure, and as described below, the spacer SPC may be arranged between pixels, such that a color patterning process may be performed using a fine metal mask (FMM). That is, the display device 1 according to the present disclosure may have pixels patterned by a single color patterning process. Thus, compared to a case where a pixel is patterned by a plurality of color patterning processes, the intermediate layer 231 on the base layer 191 may not need to be removed, such that the intermediate layer 231 may be further arranged on the base layer 191.

In an embodiment, the intermediate layer 231 may be arranged such that a part thereof arranged on the pixel electrode 211 and a part thereof arranged on the base layer 191 may be spaced apart from each other. That is, a part of the intermediate layer 231 overlapping the pixel electrode 211 and the part thereof arranged on the base layer 191 may be physically spaced apart from each other. Thus, it is possible to block a path through which outgas generated from an organic material forming the intermediate layer 231 or moisture permeated from the outside is transmitted to the pixel.

The counter electrode 251 may be arranged on the intermediate layer 231.

In an embodiment, the counter electrode 251 may be arranged to surround the intermediate layer 231 and at least a part of the barrier 190.

Specifically, as shown in FIG. 7, the counter electrode 251 may be arranged to surround at least a part of the intermediate layer 231 on the barrier 190. In some implementations, the counter electrode 251 may surround the entire intermediate layer 231 on the barrier 190. The counter electrode 251 may surround at least a part of the barrier 190, specifically, may surround at least a part of the top layer 193, and more specifically, may cover a bottom surface of the top layer 193 overhanging the body layer 192.

In an embodiment, the counter electrode 251 may extend integrally from the bottom surface of the top layer 193 toward the base layer 191. That is, the counter electrode 251 may extend from the bottom surface of the top layer 193 to surround a side surface of the body layer 192 and may further extend to the base layer 191. In this case, when the intermediate layer 231 is formed on the base layer 191, the counter electrode 251 may cover the intermediate layer 231. In other words, the counter electrode 251 may be formed to cover all of the intermediate layer 231 arranged on the top layer 193, the top layer 193 of the barrier 190, at least a part of the side surface of the body layer 192, and the base layer 191 (or the intermediate layer 231 on the base layer 191).

In an embodiment, the counter electrode 251 may include a concave portion toward the body layer 192 between the top layer 193 and the base layer 191. When expressed from another perspective, it may mean that the counter electrode 251 may be formed to be recessed toward the body layer 192 along a shape of the first tip TP1 of the top layer 193 of the barrier 190.

The spacer SPC may be arranged between pixels.

A plurality of spacers SPC may be arranged on the substrate 100. In an embodiment, the spacer SPC may be arranged between adjacent pixels.

In an embodiment, the spacer SPC may be arranged on a spacer barrier 890. Specifically, the spacer SPC may be arranged on the spacer barrier 890 where no pixels are arranged among the plurality of barriers. As shown the layers of the spacer barrier 890 are the same as the other barriers in the plurality of barriers 190 but the shape of the spacer barrier 890 may be different than barriers having a pixel arranged thereon. As such discussion of the plurality of barriers 190 hereinafter may include the spacer barriers 890.

Thus, the plurality of barriers 190 including the spacer barriers 890 may be formed on the substrate 100, and the spacer SPC may be between at least two pixels arranged on corresponding barriers in the plurality of barriers 190. For example, a spacer may be located on a spacer barrier 890 between every pixel, every two pixels, every three pixels etc. on corresponding barriers.

The spacer barrier 890 may be arranged on the substrate 100 and may be formed to extend in a direction away from the substrate 100.

In an embodiment, the plurality of barriers 190 may be conductive. In this case, the plurality of barriers 190 may be electrically connected to each other by directly contacting the counter electrode 251. When the plurality of barriers 190 and the counter electrode 251 are electrically connected to each other, the counter electrode 251 may be supplied with voltage.

In an embodiment, the plurality of barriers 190 may have a layer structure.

As a specific example, each of the barriers in the plurality of barriers 190 may include the base layer 191, the body layer 192, and the top layer 193. For example, the body layer 192 may be arranged on the base layer 191, and the top layer 193 may be arranged on the body layer 192.

The base layer 191 may be arranged on the substrate 100. For example, the base layer 191 may be arranged on the second insulating layer 116. However, the present disclosure is not limited thereto, and a layer may be further arranged between the base layer 191 and the second insulating layer 116.

In an embodiment, the base layer 191 may be integral with the substrate 100 and overlap the plurality of barriers 190. For example, the base layer 191 may be integral with the substrate 100 to form a lowermost layer among the plurality of barriers 190, as shown in FIG. 6, etc. That is, when expressed from another perspective, after the base layer 191 is formed on the substrate 100, the body layer 192 and the top layer 193 on which pixels are arranged, and the body layer 192 and the top layer 193 on which the spacers SPC are arranged may be arranged on the base layer 191.

The body layer 192 may be arranged on the base layer 191.

In an embodiment, the barrier 190 may have an undercut shape. In a specific embodiment, the body layer 192 may be formed in a shape having a width becoming narrower in a direction away from the substrate 100. For example, the body layer 192 may be roughly formed to have a trapezoidal cross section with a longer length of a side closer to the substrate 100.

The top layer 193 may be arranged on the body layer 192.

In an embodiment, the spacer barrier 890 may include a second tip TP2. For example, the top layer 193 may be formed to protrude outward more than the body layer 192. The term “outward” may mean that the top layer 193 is formed wider left and right than the body layer 192 with respect to FIG. 8.

The second tip TP2 may include a portion of the top layer 193, which extends outward more than the body layer 192.

The pixels may be arranged on the barrier 190.

In an embodiment, the spacer SPC may be formed to have a height greater than that of the pixel. Here, the height may be a value measured with respect to the substrate 100, the height of the spacer SPC may mean a height including the spacer SPC and the barrier 190, and the height of the pixel may mean a height including the barrier 190 of the pixel.

Thus, the use of an FMM becomes possible when the height of the spacer is greater than the height of the pixel. Specifically, the spacer SPC may support the FMM when the pixels are patterned using the FMM.

A first inorganic layer 310 may be arranged on the pixel and the spacer SPC. The first inorganic layer 310 may form the encapsulating member 300 described above.

The first inorganic layer 310 may prevent external moisture, foreign substances, etc., from penetrating into pixels or other elements.

Hereinafter, the principle of preventing moisture penetration according to the present disclosure will be described with reference to FIG. 8.

As shown in FIG. 8, the spacer SPC may be formed to have a height greater than that of the pixel. Thus, the display device 1 according to the present disclosure may use pixel patterning, i.e., the FMM in pixel patterning.

When the FMM is used, the FMM may contact the first inorganic layer 310 formed on the spacer SPC, and such contact may form a gap due to impression into the first inorganic layer 310. Moisture or foreign substances may penetrate through such a gap from the outside.

In this case, as the display device 1 according to the current embodiment includes the second tip TP2, a path of permeation of moisture or movement of foreign substances may be blocked. As described above, the first tip TP1 is formed on a pixel side, such that the path of permeation of moisture or movement of foreign substances may be blocked once again. Thus, as the path of permeation of moisture or movement of foreign substances is secondarily blocked, permeation of moisture or movement of foreign substances may be prevented.

Hereinafter, the display device 1 according to aspects of the present disclosure will be described.

Hereinafter, for the convenience of a description, matters that are the same as previously described or are easily applied by those of ordinary skill in the art will be omitted or briefly described.

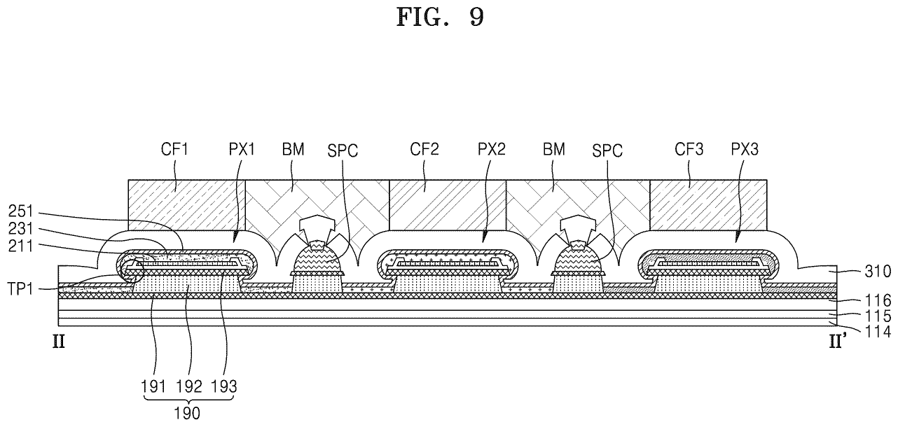

FIG. 9 is a view showing another schematic example of a cross-section II-II′ of FIG. 7.

Referring to FIG. 9, a color filter CF may be arranged on the first inorganic layer 310. The color filter CF may be arranged to overlap the pixels.

The color filter CF may be arranged to correspond to a color of light emitted from each pixel. For example, the color filter CF may include a first color filter CF1 corresponding to the first pixel PX1, a second color filter CF2 corresponding to the second pixel PX2, and a third color filter CF3 corresponding to the third pixel PX3. Each color filter CF may be arranged at a position that overlaps a corresponding pixel.

In an embodiment, a light-blocking layer BM may be further arranged on the first inorganic layer 310.

The light-blocking layer BM may be arranged between the color filters CF.

In an embodiment, the color filter CF or the light-blocking layer BM may be formed through a photolithography process.

As described above, the display device 1 according to the present disclosure may prevent moisture permeation by blocking the path of moisture permeation using the first tip TP1 and the second tip TP2. Therefore, according to the present disclosure, a wet process may be additionally performed after the formation of the first inorganic layer 310.

Specifically, since the display device 1 according to the present disclosure may be formed using a wet process after the formation of the first inorganic layer 310, photolithography may be utilized when forming a layer on the first inorganic layer 310. Accordingly, the thickness of layers formed on the first inorganic layer 310 may be formed thinner than when photolithography is not used. Accordingly, the layers (e.g., the color filter CF or light blocking layer BM) on the first inorganic layer 310 may be relatively thinned, such that the path of light may be shortened, thereby improving the optical characteristics.

Hereinafter, the display device 1 according to another embodiment of the present disclosure will be described.

For the convenience of a description, matters that are the same as previously described or are easily applied by those of ordinary skill in the art will be omitted or briefly described.

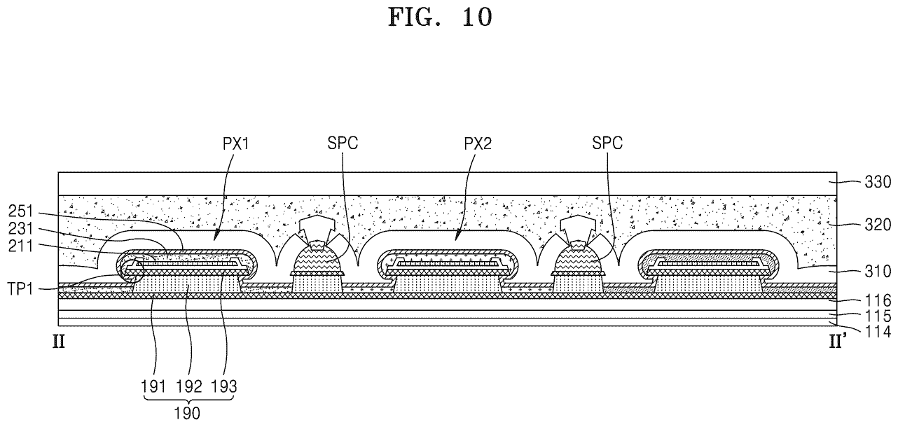

FIG. 10 is a view schematically showing another example of the cross-section II-II′ of FIG. 7.

Referring to FIG. 10, several layers may be formed on the first inorganic layer 310.

In an embodiment, a first organic layer 320 may be arranged on the first inorganic layer 310. A second inorganic layer 330 may be further arranged on the first organic layer 320.

As described above, the display device 1 according to the present disclosure may prevent moisture permeation by blocking the path of moisture permeation using the first tip TP1 and the second tip TP2. Therefore, according to the present disclosure, a wet process may be additionally performed after the formation of the first inorganic layer 310.

Specifically, as the display device 1 according to the present disclosure may be formed using a wet process after the formation of the first inorganic layer 310, photolithography may be utilized when another layer is formed on the first inorganic layer 310. Therefore, according to the present disclosure, a reflow phenomenon may be controlled when an organic layer is formed on the first inorganic layer 310. Hence, according to the present disclosure, it is possible omit dam structures from the outer surface of the display device 1 while having a similar effect as the dam structures. According to the present disclosure, as an organic layer with a low refractive index may be formed on the first inorganic layer 310, the touch sensitivity of the display device 1 of a touch type may be improved.

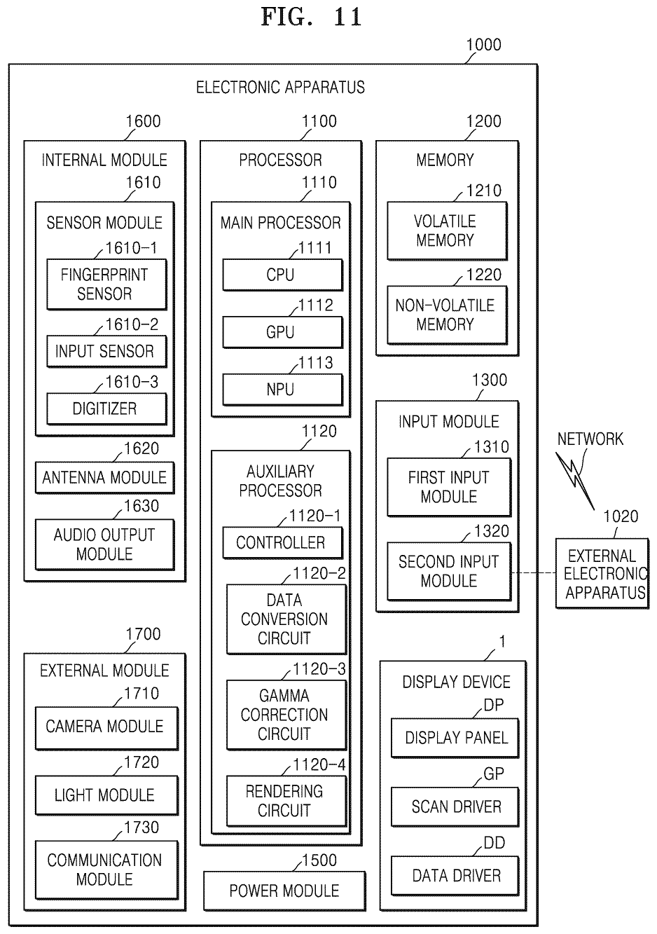

FIG. 11 is a block diagram of an electronic device according to embodiments of the present disclosure.

Referring to FIG. 11, an electronic device 1000 may output various information through the display device 1 within an operating system. The display device 1 may be a display device shown in and described with reference to FIGS. 1 to 10. When a processor 1100 executes an application stored in a memory 1200, the display device 1 may provide application information to the user through a display panel DP.

The processor 1100 may obtain an external input through an input module 1300 or a sensor module 1610 and execute an application corresponding to the external input. For example, when a user selects a camera icon displayed on the display panel DP, the processor 1190 may obtain a user input through an input sensor 1610-2 and activate a camera module 1710. The processor 1100 may transmit image data corresponding to a captured image obtained through the camera module 1710 to the display device 1. The display device 1 can display an image corresponding to a photographed image through a display panel DP.

In another example, when personal information authentication is performed in the display device 1, e.g. a fingerprint sensor 1610-1 may obtain the input fingerprint information as input data. The processor 1100 may compare the input data obtained through the fingerprint sensor 1610-1 with authentication data stored in the memory 1200 and execute an application based on a comparison result. The display device 1 may display information executed according to application's instructions through the display panel DP.

In another example, when a music streaming icon corresponding to a music streaming application displayed on the display device 1 is selected, the processor 1100 may obtain a user input through the input sensor 1610-2 and activate the music streaming application stored in the memory 1200. When a music execution command is input in the music streaming application, the processor 1100 may activate an audio output module 1630 to provide the user with audio information (e.g. music played through a speaker) corresponding to the music execution command.

So far, the operation of the electronic device 1000 has been briefly described. The configuration of the electronic device 1000 will be described in detail below. Some of the components of the electronic device 1000 described below may be integrated and provided as one component, or one component may be provided separately as two or more components.

Referring to FIG. 11, the electronic device 1000 may communicate with an external electronic device 1020 via a network (e.g., a short-range wireless communication network or a long-range wireless communication network). According to an embodiment, the electronic device 1000 may include the processor 1100, the memory 1200, an input module 1300, the display device 1, a power module 1500, an embedded module 1600, and an external module 1700. According to an embodiment, the electronic device 1000 may omit at least one of the above-described components, or may have one or more other components added. According to an embodiment, some of the components described above (e.g., the sensor module 1610, an antenna module 1620, or the audio output module 1630) may be integrated into another component (e.g., the display device 1).

The processor 1100 may execute software to control at least one other component (e.g., a hardware or software component) of the electronic device 1000 connected to the processor 1100 and may process or compute various data. According to an embodiment, the processor 1100 as at least a part of data processing or operations may store a command or data received from another component (e.g., the input module 1300, the sensor module 1610, or a communication module 1730) in a volatile memory 1210, process the command or data stored in the volatile memory 1210, and store resulting data in a non-volatile memory 1220.

The processor 1100 may include a main processor 1110 and an auxiliary processor 1120. The processor may include one or more processors. It should be understood that the one or more processors may act either individually or collectively to carry out operations. The main processor 1110 may include one or more of a central processing unit (CPU) 111-1 or an application processor (AP). The main processor 1110 may further include any one or more of a graphic processing unit (GPU) 1110-2, a communication processor (CP), and an image signal processor (ISP). The main processor 1110 may further include a neural processing unit (NPU) 1110-3. The NPU 1110-3 may be a processor specialized in processing an AI model that may be generated through machine learning. The AI model may include a plurality of artificial neural network layers. The artificial neural network may be, but not limited to, a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof. In some implementations, the AI model may include a software structure as well as the hardware structure. In some implementations the AI model may include a software structure or a hardware structure. The main processor described above may be implemented with at least two of the processing units as a single integrated configuration (e.g., a single chip) or each may be implemented as an independent configuration (e.g., a plurality of chips).

The auxiliary processor 1120 may include a controller 1120-1. The controller 1120-1 may include an interface conversion circuit and a timing control circuit. The controller 1120-1 may receive an image signal from the main processor 1110, convert a data format of the image signal to match interface specifications with the display device 1, and output the image data. The controller 1120-1 may output various control signals necessary for driving the display device 1.

The auxiliary processor 1120 may further include the controller 1120-1, a data conversion circuit 1120-2, a gamma correction circuit 1120-3, a rendering circuit 1120-4, etc. The data conversion circuit 1120-2 may receive image data from the controller 1120-1 and compensate for the image data to display the image at a desired brightness according to the characteristics of the electronic device 1000, the user's settings, etc., or convert the image data to reduce power consumption or compensate for afterimages. The gamma correction circuit 1120-3 may convert the image data or a gamma reference voltage, etc. such that the image displayed on the electronic device 1000 has desired gamma characteristics. The rendering circuit 1120-4 receives image data from the controller 1120-1 and can render the image data by taking into consideration the pixel layout of the display panel DP applied to the electronic device 1000. At least one of the data conversion circuit 1120-2, the gamma correction circuit 1120-3, and the rendering circuit 1120-4 may be integrated into another component (e.g., the main processor 1110 or the controller 1120-1). At least one of the data conversion circuit 1120-2, the gamma correction circuit 1120-3, and the rendering circuit 1120-4 may be integrated into the data driver DD described below.

The memory 1200 may store various data used by at least one component of the electronic device 1000 (e.g., the processor 1100 or the sensor module 1610) and input data or output data for commands related thereto. The memory 1200 may include at least one of the volatile memory 1210 and the non-volatile memory 1220.

The input module 1300 may receive commands or data to be used for components of the electronic device 1000 (e.g., the processor 1100, the sensor module 1610, or the audio output module 1630) from an external source of the electronic device 1000 (e.g., the user or the external electronic device 1020).

The input module 1300 may include a first input module 1310 into which a command or data is input from the user and a second input module 1320 into which a command or data is input from the external electronic device 1020. The first input module 1310 may include a microphone, a mouse, a keyboard, a key (e.g., a button), or a pen (e.g., a passive pen or an active pen). The second input module 1320 may support a designated protocol that may be connected wired or wirelessly to the external electronic device 1020. According to an embodiment, the second input module 1320 may include, for example and without limitation, a high-definition multimedia interface (HDMI), a universal serial bus (USB) interface, a secure digital (SD) card interface, or an audio interface. The second input module 1320 may include a connector that may be physically connected to the external electronic device 1020, for example, an HDMI connector, a USB connector, an SD card connector, or an audio connector (e.g., a headphone connector).

The display device 1 may visually provide information to the user. The display device 1 may include the display panel DP, a scan driver GP, and a data driver DD. The display device 1 may further include a window, a chassis, and a bracket to protect the display panel DP.

The display panel DP may further include a light-emitting driver. The light-emitting driver may output a light-emitting control signal to the display panel DP in response to the control signal received from the controller 1120-1. The light-emitting driver may be formed separately from the scan driver GP or may be integrated into the scan driver GP.

The scan driver GP may receive a control signal from the controller 1120-1 and output a scan signal to the display panel DP in response to the control signal. For example, a control signal generated from the controller 1120-1 and transmitted to the scan driver GP may be a scan input signal for controlling the scan driver GP. The scan input signal may be an input signal applied to switching elements included in stages of the scan driver GP.

The data driver DD may receive the control signal from the controller 1120-1, convert image data into an analog voltage (e.g., a data voltage) in response to the control signal, and then output the data voltage to the display panel DP. For example, a control signal generated from the controller 1120-1 and transmitted to the data driver DD may be a data input signal for controlling the data driver DD.

The data driver DD may be integrated into another component (e.g., the controller 1120-1). The functions of the interface conversion circuit and the timing control circuit of the above-described controller 1120-1 may be integrated into the data driver DD.

The controller 1120-1 may generate a clock signal required for driving the scan driver GP. Each stage of the scan driver GP may operate based on a clock signal corresponding to each stage.

The scan driver GP may generate a scan signal based on a scan input signal, a clock signal, and a scan input voltage. The scan signal may be transmitted to a pixel circuit, and a thin-film transistor included in the pixel circuit may be driven based on the scan signal. The scan signal may be transmitted to a gate included in the pixel circuit.

The display device 1 may further include a light-emitting driver and a voltage generation circuit. The voltage generation circuit may output various voltages required to drive the display panel DP.

The power module 1500 may supply power to the components of the electronic device 1000. The power module 1500 may generate a gate driving voltage (e.g., Gate High Voltage, Gate Low Voltage) required to drive the scan driver GP.

For example, the power module 1500 may mean a power generation unit, a power supply, etc. For example, the power module 1500 may include a battery that performs charging with the power voltage. The battery may include a non-rechargeable primary battery, a rechargeable secondary battery, or a fuel cell.

For example, the power module 1500 may include a power management integrated circuit (PMIC). The PMIC may provide optimized power for each of the modules described above and below.

For example, the power module 1500 may include a wireless power transmission/reception member electrically connected to the battery. The wireless power transmission/reception member may include a plurality of coil-shaped antenna radiators.

The electronic device 1000 may further include the embedded module 1600 and the external module 1700. The embedded module 1600 may include the sensor module 1610, the antenna module 1620, and the audio output module 1630. The external module 1700 may include the camera module 1710, the light module 1720, and the communication module 1730.

The sensor module 1610 may detect an input by the user's body or an input by the pen of the first input module 1310 and generate an electric signal or data value corresponding to the input. The sensor module 1610 may include at least any one of the fingerprint sensor 1610-1, the input sensor 1610-2, and a digitizer 1610-3.

The fingerprint sensor 1610-1 may generate a data value corresponding to the user's fingerprint. The fingerprint sensor 1610-1 may include for example and without limitation an optical fingerprint sensor or a capacitive fingerprint sensor.

The input sensor 1610-2 may generate a data value corresponding to coordinate information of the input by the user's body or the input by the pen. The input sensor 1610-2 may generate for example and without limitation, as the data value, a change in capacitance due to the input. The input sensor 1610-2 may detect an input from a passive pen or transmit and receive data with an active pen.

The input sensors 1610-2 may also measure bio-signals such as blood pressure, moisture, or body fat. For example, when the user touches the body part to a sensor layer or a sensing panel and does not move for a certain period of time, the input sensor 1610-2 may detect a bio signal based on a change in an electric field due to the body part and output the user-desired information to the display device 1.

The digitizer 1610-3 may generate a data value corresponding to coordinate information input by the pen. The digitizer 1610-3 may generate, as a data value, an electromagnetic change due to the input. The digitizer module 1610-3 may detect an input from a passive pen or transmit and receive data with an active pen.

At least one of the fingerprint sensor 1610-1, the input sensor 1610-2, and the digitizer 1610-3 may be implemented as a sensor layer formed on the display panel DP through a continuous process. The fingerprint sensor 1610-1, the input sensor 1610-2, and the digitizer 1610-3 may be arranged on the display panel DP, and one of the fingerprint sensor 1610-1, the input sensor 1610-2, and the digitizer 1610-3, for example, the digitizer 1610-3, may be arranged under the display panel DP.

At least two of the fingerprint sensor 1610-1, the input sensor 1610-2, and the digitizer 1610-3 may be formed to be integrated into one sensing panel through the same process. When integrated into one sensing panel, the sensing panel may be arranged between the display panel DP and a window arranged on the display panel DP. According to an embodiment, the sensing panel may be arranged on the window, and the position of the sensing panel is not particularly limited.

At least one of the fingerprint sensor 1610-1, the input sensor 1610-2, and the digitizer 1610-3 may be embedded in the display panel DP. That is, through a process of forming elements (e.g., light-emitting elements, transistors, etc.) included in the display panel DP, at least one of the fingerprint sensor 1610-1, the input sensor 1610-2, and the digitizer 1610-3 may be formed at the same time.

The sensor module 1610 may generate an electrical signal or a data value corresponding to an internal or external state of the electronic device 1000. The sensor module 1610 may further include a gesture sensor, a gyro sensor, a pressure sensor, a magnetic sensor, an acceleration sensor, a grip sensor, a proximity sensor, a color sensor, an IR ray sensor, a vivo sensor, a temperature sensor, a humidity sensor, and/or an illuminance sensor.

The antenna module 1620 may include one or more antennas for transmitting a signal or power to the outside or receiving a signal or power from the outside. According to an embodiment, the communication module 1730 may transmit a signal to an external electronic device or receive a signal from the external electronic device through an antenna suitable for a communication scheme. An antenna pattern of the antenna module 1620 may be integrated into one component of the display device 1 (e.g., the display panel DP) or the input sensor 1610-2.

The audio output module 1630 may be a device for outputting an audio signal to the outside of the electronic device 1000, and may include, for example, a speaker used for general purposes such as multimedia playback or recording playback, and a receiver used exclusively for phone reception. According to an embodiment, the receiver may be implemented separately from or as a part of the speaker. The audio output pattern of the audio output module 1630 may be integrated into the display device 1.

The camera module 1710 may capture visual data corresponding a still image and/or visual data corresponding to two or more images e.g. a moving image (i.e. video). According to an embodiment, the camera module 1710 may include one or more lenses, image sensors, or image signal processors. The camera module 1710 may further include an infrared camera capable of measuring the presence or absence, the position, or line of sight of the user, etc.

The light module 1720 may provide light. The light module 1720 may include a light-emitting diode or a xenon lamp. The light module 1720 may operate in conjunction with or independently of the camera module 1710.

The communication module 1730 may support the establishment of a wired or wireless communication channel between the electronic device 1000 and the external electronic device 1020, and the performance of communication through the established communication channel. The communication module 1730 may include any one or all of a wireless communication module (e.g., a cellular communication module, a short-range wireless communication module, a global navigation satellite system (GNSS) communication module) and a wired communication module (e.g., a local area network (LAN) communication module or a power line communication module). The communication module 1730 may communicate with the external electronic device 1020 via a short-range communication network such as Bluetooth, Wi-Fi direct, or infrared data association (IrDA), or a long-range communication network such as a cellular network, the Internet, or a computer network (e.g., a LAN or WAN). Various types of communication module 1730 described above may be implemented as one chip or as separate chips.

The input module 1300, the sensor module 1610, the camera module 1710, etc., may be used to control the operation of the display device 1 in conjunction with the processor 1100.

The processor 1100 may output a command or data to the display device 1, the audio output module 1630, the camera module 1710, or the light module 1720 based on input data received from the input module 1300. For example, the processor 1100 may generate the image data in response to the input data received through the mouse or the active pen and output the image data to the display device 1, or generate command data in response to the input data and output the image data to the camera module 1710 or the light module 1720. When no input data is received from the input module 1300 for a certain period of time, the processor 1100 may reduce power consumption in the electronic device 1000 by switching the operation mode of the electronic device 1000 to a low-power mode or a sleep mode.

The processor 1100 may output a command or data to the display device 1, the audio output module 1630, the camera module 1710, or the light module 1720 based on sensing data received from the sensor module 1610. For example, the processor 1100 may compare authentication data applied by the fingerprint sensor 1610-1 with authentication data stored in the memory 1200 and execute an application based on the comparison result. The processor 1100 may execute a command or output corresponding image data to the display device 1 based on the sensing data sensed by the input sensor 1610-2 or the digitizer 1610-3. When a temperature sensor is included in the sensor module 1610, the processor 1100 may receive temperature data on the temperature measured from the sensor module 1610 and perform brightness correction, etc., on the image data based on the temperature data.

The processor 1100 may receive measurement data on the presence or absence, position, and line or sight of the user, etc., from the camera module 1710. The processor 1100 may further perform brightness correction, etc., on the image data based on the measurement data. For example, the processor 1100 that determines the presence or absence of the user through the input from the camera module 1710 may output the image data with brightness corrected through the data conversion circuit 1120-2 or the gamma correction circuit 1120-3 to the display device 1.

Two or more of the components may be connected to one another via a communication scheme between peripheral devices (e.g., a bus, general purpose input and output (GPIO), a serial peripheral interface (SPI), a mobile industry processor interface (MIPI), or an ultra-path interconnect (UPI) link) to exchange signals (e.g., a command or data). The processor 1100 may communicate with the display device 1 through a mutually agreed interface, and may use, for example, any one of the above-described communication schemes, and is not limited to the above-described communication schemes.

The electronic device 1000 according to various embodiments disclosed herein may be devices of various forms. The electronic device 1000 may include, for example, at least one of a portable communication device (e.g., a smartphone), a computer device, a portable multimedia device, a portable medical device, a camera, a wearable device, or a home appliance device. The electronic device 1000 according to an embodiment herein is not limited to the devices described above.

In an embodiment, the display device 1 may include the display panel DP and the scan driver GP. The controller 1120-1 may generate a scan input signal required for driving the scan driver GP. The power module 1500 may generate a scan input voltage required for driving the scan driver GP under the control of the processor or controller 1120-1. For example, the scan input voltage may be a gate driving voltage.

The display panel DP may be divided into the display area DA where the pixel circuit is arranged and the peripheral area PA on the periphery of the display area DA. As described above, a region where an image is displayed may be the display area DA, and a region outside the display area DA where an image is not displayed may be the peripheral area PA.

The scan driver GP may be arranged in the peripheral area PA and may receive a scan input signal from the controller 1120-1 and a scan input voltage from the power module 1500. The scan driver GP may generate or output a scan signal based on the scan input signal and/or the scan input voltage. The scan signal may be transmitted from the scan driver GP to the pixel circuit.

In an embodiment, the scan driver GP may include at least one capacitor. At least one capacitor may include a first electrode and a second electrode. For example, the first electrode may be a signal line that transmits at least one of the scan input signal or the scan input voltage. For example, the first electrode may be at least a part of the signal line that transmits at least one of the scan input signals or the scan input voltage. The signal line may be, for example, a wire through which the scan input voltage is transmitted.

For example, the second electrode may overlap the first electrode. The second electrode may overlap the signal line that transmits at least one of the scan input signals or the scan input voltage. For example, the second electrode may overlap at least a part of the signal line that transmits at least one of the scan input signals or the scan input voltage.

In an embodiment, the peripheral area PA may include a wire arrangement area in which wires are arranged, and a circuit arrangement area in which at least one transistor is arranged between the display area DA and the wire arrangement area. For example, at least one capacitor may be arranged in the wire arrangement area. At least one capacitor may be arranged in the wire arrangement area.

As such, according to the present disclosure, as the pixel layer PXL may be formed using a metal mask, the first pixel PX1, the second pixel PX2, and the third pixel PX3 may be formed with a single color patterning process without a color patterning process for each of them.

According to the present disclosure, even when a gap is formed in the spacer SPC, it is possible to prevent the pixel electrode, the counter electrode, etc., from being corroded or damaged due to a short-circuit in the intermediate layer 231.

According to the present disclosure, as the path of moisture permeation is blocked by the short-circuit in the intermediate layer 231, a wet process may be further performed after the formation of the first inorganic layer.

According to the present disclosure, the color filter CF on the first inorganic layer may be formed by a photolithography process, such that the path of light may be shortened, thereby improving the optical characteristics.

Embodiments of the present disclosure may provide a display device having improved optical characteristics and an electronic device including the display device.

However, these effects are exemplary, and the effects of the present disclosure are not limited thereto.

Each of the embodiments described above may be implemented independently, but the structure of each embodiment may also be applied in combination to other embodiments.

Although the present disclosure has been described with reference to an example shown in the drawings, it will be understood by those of ordinary skill in the art that various modifications and equivalent other examples may be made from the shown example. Accordingly, the true technical scope of the present disclosure should be defined by the technical spirit of the appended claims.

Specific implementations described in the embodiments are examples and do not limit the scope of the embodiments in any way. When there is no specific mentioning, such as “essential” or “important”, it may not be a necessary component for the application of the present disclosure.

In the specification (especially, claims) of the present disclosure, the use of the term “the” and similar indicators thereof may correspond to both the singular and the plural. In addition, when the range is described in the embodiments, the range includes the present disclosure to which an individual value falling within the range is applied (unless stated otherwise), and is the same as the description of an individual value constituting the range in the description of the present disclosure. Finally, when there is no apparent description of the order of operations constituting the method according to embodiments or a contrary description thereof, the operations may be performed in an appropriate order. However, the embodiments are not necessarily limited according to the describing order of the operations. The use of all examples or exemplary terms in the present disclosure are to simply describe the embodiments in detail, and unless the range of the embodiments is not limited by the examples or the exemplary terms unless limited by the claims. In addition, it may be understood by those of ordinary skill in the art that various modifications, combinations, and changes may be made according to design conditions and factors within the scope of the appended claims or equivalents thereof.

What is claimed is:

1. A display device comprising:
a substrate comprising a display area and a peripheral area outside the display area;
a plurality of barriers arranged on the substrate;
a plurality of pixels wherein a pixel in the plurality of pixels is arranged on a barrier in the plurality of barriers and wherein the pixel in the plurality of pixels comprises a pixel electrode, an intermediate layer, and a counter electrode; and
a spacer arranged between at least two pixels in the plurality of pixels.

2. The display device of claim 1, wherein the pixel electrode is arranged on the barrier and comprises a pixel-defining film arranged on the barrier to cover at least a part of the pixel electrode.

3. The display device of claim 1, wherein the barrier comprises:
a base layer arranged on the substrate;
a body layer arranged on the base layer; and
a top layer arranged on the body layer.

4. The display device of claim 3, wherein the base layer is integral with the substrate and overlaps the plurality of barriers.

5. The display device of claim 3, wherein the body layer has a width that becomes narrower in a direction away from the substrate.

6. The display device of claim 3, wherein the barrier comprises a first tip having the top layer that protrudes outward more than the body layer to overhang the body layer.

7. The display device of claim 3, wherein the intermediate layer is arranged to surround at least a part of the pixel electrode and the barrier.

8. The display device of claim 3, wherein the intermediate layer is further arranged on the base layer.

9. The display device of claim 8, wherein the intermediate layer is arranged such that a part is arranged on the pixel electrode and a part is arranged on the base layer and wherein the part arranged on the pixel electrode is spaced apart from the part arranged on the base layer.

10. The display device of claim 3, wherein the counter electrode is arranged to surround at least a part of the intermediate layer and the barrier.

11. The display device of claim 3, wherein the counter electrode includes a concave portion toward the body layer between the top layer and the base layer.

12. The display device of claim 1, wherein the spacer is has a height greater than that of the pixel.

13. The display device of claim 1, wherein the spacer is arranged on a spacer barrier in the plurality of barriers wherein the pixel is not arranged on the spacer barrier.

14. The display device of claim 13, wherein the spacer barrier comprises:
a base layer arranged on the substrate;
a body layer arranged on the base layer; and
a top layer arranged on the body layer.

15. The display device of claim 14, wherein the spacer barrier comprises a second tip that has the top layer that protrudes outward more than the body layer to overhang the body layer.

16. The display device of claim 1, further comprising a first inorganic layer arranged on the pixel and the spacer.

17. The display device of claim 16, further comprising a color filter arranged on the first inorganic layer and arranged to overlap the pixel.

18. The display device of claim 16, further comprising a first organic layer arranged on the first inorganic layer.

19. The display device of claim 18, further comprising a second inorganic layer arranged on the first organic layer.

20. An electronic device comprising:
a controller configured to generate a scan input signal;
a power module configured to generate a scan input voltage; and
a display device divided into a display area in which a pixel circuit is arranged and a peripheral area located outside the display area and comprising a pad area,
wherein the display device comprises:
a substrate;
a plurality of barriers arranged on the substrate;
a plurality of pixels wherein a pixel in the plurality of pixels is arranged on a barrier in the plurality of barriers and wherein the pixel in the plurality of pixels includes a pixel electrode, an intermediate layer, and a counter electrode; and
a spacer arranged between at least two pixels in the plurality of pixels.
